(19) United States
(12) Patent Application Publication
(10) Pub. No.: US 2012/0286306 A1
(43) Pub. Date: Nov. 15, 2012

(54) DIFFUSELY RADIATING LED LIGHT SYSTEM

(75) Inventors: Carsten Dam-Hansen, Tastrup (DK); Paul Michael Petersen, Hillerod (DK); Peter Behrensdorff Poulsen, Soborg (DK)

(73) Assignee: DANMARKS TEKNISKE UNIVERSITET, Kgs. Lyngby (DK)

(21) Appl. No.: 13/509,184

(22) PCT Filed: Nov. 11, 2010
(86) PCT No.: PCT/EP10/67285

§ 371 Date: Aug. 1, 2012

Related U.S. Application Data
(60) Provisional application No. 61/260,219, filed on Nov. 11, 2009.

(51) Int. Cl. H01L 33/08; H01L 33/60

(52) U.S. Cl. 257/89; 257/E33.072

(57) ABSTRACT

A lighting device (7) for illuminating objects, the lighting device comprising: a plurality of light emitting diodes (1) wherein at least one of the plurality of light emitting diodes is adapted to generate light having a spectrum different from a spectrum of light generated by another light emitting diode of said plurality of light emitting diodes; and a chamber (8) comprising a first reflective surface (3a) and an opening (5) for allowing light to exit said chamber, said opening having a periphery, wherein the plurality of light emitting diodes (1) are positioned along the periphery of said opening. The opening (5) has a centre point defined as the centroid of said opening, and that said plurality of light emitting diodes are positioned along a limited portion of the periphery of said opening, wherein an angular distance between any two light emitting diodes of said lighting device relative the centre point of the opening is smaller than 135 degrees and said first reflective surface (3a) is a diffuse reflective surface.

### FIELD OF THE INVENTION

The present invention relates to lighting devices, more specifically to a high quality lighting device comprising a plurality of light emitting diodes.

### BACKGROUND OF THE INVENTION

The traditional incandescent bulb is a high quality light source generating a light with a spectrum close to the spectrum of black body radiator, this results in good colour rendering properties. However, incandescent bulbs use a large amount of energy (compared to the generated visible light), resulting in a corresponding large outlet of CO₂.

Compact fluorescent light bulbs have been proposed as an alternative to incandescent bulbs. However, the spectrum of the light generated by compact fluorescent light bulbs differs significantly from that of black body radiators and incandescent bulbs, and as a result the colour rendering properties of the light is low. Lighting devices using light emitting diodes (LED) have the potential to generate high quality light having a spectrum close to that of black body radiators, while using only a small amount of energy (compared to the generated visible light). Generally, LED-based systems may be configured to produce light with desired spectral properties, depending on the intended application, e.g a spectral distribution providing a high quality colour rendering. LEDs further have the advantage that they produce a very limited amount of heat radiation. This makes them a good choice in situations where the object to be illuminated is heat sensitive, such as special food products or museum specimens.

Specifically lighting devices comprising a plurality of different coloured LEDs have the ability to generate high quality light.

WO2005105381 discloses a method for illumination of a subject by determining settings for colour inputs and applying those settings to one or more systems that generate and mix colours of light, so as to provide combined light of the desired character. The system may comprise an optical integrating cavity that reflects light coming from LEDs with three or more colours. The system is however very complex, thus making the lighting device expensive. This will make the system unavailable to a large group of potential users.

There is thus a need for a lighting device that has the ability to create high quality light having desired spectral properties, low energy consumption and a low production cost making the device available to the broad public.

### SUMMARY

According to a first aspect the invention relates to a lighting device for illuminating objects, the lighting device comprising:
a plurality of light emitting diodes wherein at least one of the plurality of light emitting diodes is adapted to generate light having a spectrum different from a spectrum of light generated by another light emitting diode of said plurality of light emitting diodes; and
a chamber comprising a first reflective surface, and an opening for allowing light to exit said chamber, said opening having a periphery, wherein the plurality of light emitting diodes are positioned along the periphery of said opening and wherein said shielding structure is adapted to prevent light rays from said plurality of light emitting diodes to exit said opening without being reflected by said reflective surface at least once;

characterized in that said opening has a centre point defined as the centroid of said opening, and that said plurality of light emitting diodes are positioned along a limited portion of the periphery of said opening, wherein an angular distance between any two light emitting diodes of said lighting device relative to the centre point of the opening is smaller than 135 degrees and said first reflective surface is a diffuse reflective surface.

In one embodiment of the invention, the angular distance between any two light emitting diodes with respect to the centre point is below 90 degrees.

In one embodiment of the invention, the angular distance between any two light emitting diodes with respect to the centre point is below 45 degrees.

In one embodiment of the invention, the angular distance between any two light emitting diodes with respect to the centre point is below 30 degrees.

It is understood that the angular distance between two light emitting diodes with respect to the centre is the smallest angular distance between the light emitting diodes e.g. the angular distance that is at most 180 degrees.

In one embodiment the chamber of said lighting device further comprises a shielding structure wherein said shielding structure is adapted to prevent light rays from said plurality of light emitting diodes to exit said opening without being reflected by said reflective surface at least once.

The light emitting diodes may be any type of light emitting diodes. Preferably the light generated by the light emitting diodes is mainly within the spectrum that is visible to the human eye. The chamber may be any cavity suitable for mixing light from a plurality of light emitting diodes. The chamber has preferably a concave shape. The opening of the chamber may have any shape such as elliptic, circular, rectangular or it may even have a complex 3-dimensional shape. The diffuse reflective surface of the chamber may cover a part of the surface of the chamber or the entire chamber. The diffuse reflective surface may be the inner wall or walls of the chamber or parts of the inner wall/s, or alternatively a coating applied to the inner wall/s, The diffuse reflective surface may also be a separate structure or a surface coating of a separate structure,

The diffuse reflective surface may be made of any suitable material providing diffuse reflections, e.g. Lambertian or near-Lambertian reflections for mixing the LED light. In some embodiments the diffuse reflective surface may reflect 80-100% of the incoming light energy over the spectral range between 250-2500 nm, preferably in the range 300 nm-1100nm, more preferably 350-780 nm. Examples of suitable diffuse reflective surfaces are described in U.S. Pat. No. 5,596,450 and U.S. Pat. No. 5,976,686.

The shielding structure may be an integral part of the chamber or a separate structure. The surface of the shielding structure is preferably made of a material with high reflective properties securing that most of the light incident on the shielding structure is reflected back.

The shielding structure may function to prevent the majority of light from the plurality of light emitting diodes from exiting said opening without being reflected by said reflective surface at least once, preferably 70% of the energy of the light generated by the light emitting diodes is prevented from exiting said opening without being reflected by said reflective surface at least once, more preferably 90% of the energy of the light generated by the light emitting diodes is prevented from exiting said opening without being reflected by said reflective surface at least once, even more preferably 95% of the energy of the light generated by the light emitting diodes is prevented from exiting said opening without being reflected by said reflective surface at least once. In some embodiments, all of the energy of the light generated by the light emitting diodes is prevented from exiting said opening without being reflected by said reflective surface at least once.

In one embodiment the light emitting diodes are positioned on the shielding structure and the shielding structure is provided with electrical contact means for providing electrical power to the light emitting diodes. The shielding structure may be made of a material with good heat transferring capabilities such as a material with a high thermal conductivity. Examples of suitable materials include metals such as aluminium or copper. The shielding structure may be a printed circuit board, preferably with a high thermal conductivity, such as a two- or multi-layer FR4 print with thermal vias or a MCPCB, Metal Core printed circuit board. Thereby heat generated by the light emitting diodes may be transferred to the surroundings.

Any number of light emitting diodes may be used. The spectral differences between the light generated by the light emitting diodes, corresponds preferably to different visible colours e.g. red, blue, green and white. Any number of types of light emitting diodes generating different coloured light may be used. Preferably a limited number of light emitting diodes is used, such as below 10, more preferably below 5, even more preferably 2 light emitting diodes may be used. There may also be a plurality of light emitting diodes generating light having similar spectral properties. By restricting the positioning of light emitting diodes to a limited part of the periphery of the opening, fewer light emitting diodes may be used. This will lower the overall number of components in the device, thereby lowering the production cost.

It is an important characteristic for a high quality lighting device, in certain applications, that an approximately directionally symmetric distribution of light is generated. It has been found out that a lighting device having only light emitting diodes positioned in one side of the opening of the device and comprising a diffuse reflective surface can generate light having a directional distribution of light that is sufficiently symmetric for most applications.

By only positioning light emitting diodes within a limited portion of the periphery, less space is needed for electronic wiring. This enables simpler designs. As most LEDs produce a significant amount of heat, a device according to the present invention may be fitted with cooling means only at the part of the periphery of the lighting device where the light emitting diodes are positioned. Thereby a simple and efficient cooling is achieved, in a cost effective manner. This further decreases the production cost of the device.

By having light emitting diodes with varying colours positioned close to each other, the geometrical relationship between each of the light emitting diodes and the chamber becomes similar, resulting in an effective mixing of the light. This secures that the colour of the light exiting the chamber is approximately directionally independent. In contrast, the colour of the light of a similar system where the distances between the differently coloured light emitting diodes are large may be highly dependent on directionality, such that light shining in one direction has a different colour than light shining in another direction. This will generate the generally undesired effect of multiple different coloured shadows behind illuminated objects and/or inhomogeneous illumination. Directional independence of the generated light may be very important when the lighting device is used as a high quality lighting device e.g. for lighting paintings or museum specimens where an accurate and even representation of the colours is of importance.

In one embodiment the area of said opening of said chamber is at least 20 times larger than the total light emitting surface area of all light emitting diodes of the lighting device.

In one embodiment the area of said opening of said chamber is at least 30 times larger than the total light emitting surface area of all light emitting diodes of the lighting device.

By having a large opening of the (diffusely reflecting) chamber relative to the total light emitting surface area of the light emitting diodes a (soft) diffuse light results with a lower luminance and hence reduced glare. The glare is especially a problem for LED based lamps as the light emitting surface area of a light emitting diode is small compared to the emitted light intensity, hence a high luminance, resulting in problems with glare.

In one embodiment the lighting device further comprises an optical filter positioned so as to cover at least part of the opening of the inner chamber, wherein the optical filter is adapted to modify the spectrum of the light exiting the opening increasing the colour rendering properties.

In some embodiment, the optical filter covers the entire opening causing all light exiting the chamber to pass through the optical filter.

In one embodiment, the optical filter comprises a wavelength converting component adapted to modify the wavelength distribution of at least a part of the emitted light so as to modify the spectral distribution of the light exiting the opening of the chamber. The wavelength converting component may be a photoluminescent, i.e. fluorescent and/or phosphorescent, material adapted to absorb light of a first frequency range and to re-emit the absorbed light energy as light of a second frequency range different from the first frequency range, e.g. a range of lower frequencies than the first frequency range. Hence the spectral distribution of the emitted light may be modified without unnecessarily reducing the emitted light intensity. Alternatively or additionally, at least a part of the diffuse reflective surface may comprise such a wavelength converting component, e.g. in the form of a photoluminescent coating. Other examples of suitable wavelength converting components include quantum dots and/or other materials having down or up-converting properties to light.

The colour rendering properties may be measured by the general colour rendering index (CRI) or specific indices. Alternatively, the colour rendering properties may be measured by another suitable colour rendering metric. The colour rendering index (CRI) is a colour rendering metric which compares the appearance of different coloured test objects illuminated by the test light source compared to the appearance of these under illumination by a black body radiator or daylight with the same correlated colour temperature (CCT) as the test light source. The CRI is a good measure when you want to replace incandescent light sources and obtain the same light quality. There are other colour rendering metrics, like the Gamut area index and the full spectrum index that might be a better measure in other applications.

The optical filter may be any kind of optical filter such as a colour filter (plastic or glass coloured filter) that absorbs light within a predetermined range/s of wavelengths or a dichroic filter that reflects light within a predetermined range/s of wavelengths.

By having an optical filter placed in front of the chamber the combined spectrum generated by the plurality of LEDs may further be modified. This is especially beneficial for a lighting device as disclosed herein as such a lighting device may only need a limited number of LEDs to provide the desired spectral distribution of the light exiting the lighting device. Thereby a more flexible lighting device is achieved. The optical filter may be used to further adjust the correlated colour temperature of the generated light to match that of low power incandescent bulbs.

In one embodiment the lighting device further comprises a controlling circuit adapted to modify the intensity of the plurality of light emitting diodes for allowing the lighting device to be dimmed without significantly affecting the spectrum of the generated light.

As the spectrum of the light generated by a light emitting diode changes as a function of the operation current and temperature of that light emitting diode, the overall spectrum of a lighting device comprising a plurality of light emitting diodes will change when the lighting device is dimmed.

By having a lighting device comprising controlling means, adapted to modify the intensity of the plurality of light emitting diode, the lighting device may be dimmed without significantly affecting the spectrum of the generated light.

The control circuit may be provided with information of the spectral properties, of the plurality of light emitting diodes, as a function of their individual operation current and temperature.

According to a second aspect, the invention relates to a lighting apparatus comprising a plurality of lighting devices as defined above or in the following wherein the lighting apparatus comprises an elongated casing having a centre line wherein the plurality of lighting devices are arranged along said centre line, and said portion of the periphery where the plurality of light emitting diodes are positioned is in proximity of the centre line.

In one embodiment the angle between a line starting in the centre point of the opening of a lighting device and going through any of the plurality of light emitting diodes of said lighting device and a tangent to said centre line in the centre point of the opening of said lighting device is at most 45 degrees e.g. at most 30 degrees.

It is understood that the angle between the axis and the line is the smallest angle of the two possible angles e.g. the angle that is at most 180 degrees.

The lighting devices may be positioned so that their respective openings point in a common direction. The plurality of lighting devices may generate light with a varying spectrum or a similar spectrum. The casing may have any shape. Preferably the casing has a rectangular shape. Preferably the distance between two lighting devices is at least equal to one time the widest part of the opening of a lighting device. Preferably the distance between two lighting devices is at least equal two times the widest part of the opening of a lighting device. The casing may be provided with electrical contact means for providing electrical power to the lighting devices.

In one embodiment said casing is made of a material having high thermal conductivity, such as a metal, e.g. copper or aluminium, optionally with a matte coating or anodising of the surface.

Preferably the LEDs are positioned on the shielding structure and the shielding structure is attached to the casing so as to be in a good thermal contact with the elongated casing with a large area to the surroundings. Thereby an efficient heat transfer away from the lighting devices is provided.

By approximately centering the portion of the periphery where the LEDs are positioned around the centre line of the lighting apparatus the whole casing can function as a heat sink for the lighting devices. In contrast if LEDs are placed around the entire periphery, the LEDs positioned farthest away from the axis of the lighting apparatus would have low heat transferring means.

In one embodiment the chamber is dome shaped, such as spherical or hemispherical.

In one embodiment the plurality of Light emitting diodes is arranged to predominantly radiate away from said opening.

According to a third aspect the invention relates to a lighting device for illuminating objects, the lighting device comprising:
a plurality of light emitting diodes wherein at least one of the plurality of light emitting diodes is adapted to generate light having a spectrum different from a spectrum of light generated by another light emitting diode of said plurality of light emitting diodes; and
a chamber comprising a first reflective surface, an opening for allowing light to exit said chamber, said opening having a periphery, wherein the plurality of light emitting diodes are positioned along the periphery of said opening;

wherein the area of said opening of said chamber is at least 20 times larger than the total light emitting surface area of all light emitting diodes of the lighting device.

In one embodiment the area of said opening of said chamber is at least 30 times larger than the total light emitting surface area of all light emitting diodes of the lighting device.

A lighting device according to the present invention can be used in all kinds of lighting systems, where high light quality and perfect colour mixing is of importance. Be it for example light fixtures for showcase lighting, down lights, up lighters, desk lamps, floor lamps, wall mounted lamps, outdoor lamps etc. The invention is particularly suitable for RGB LED-based light systems as well as systems where specific colours are added to a white LED. LED systems with 2 or more LEDs changing the light spectrum from the light source during operation are possible applications of the invention. The lighting systems can e.g. be used to, enhance wellbeing in office environments by light quality, giving a preferred colour or colour tuning to the user of the light, show exhibited objects perfectly in show cases without having IR or UV radiation affecting the objects, achieving better contrast for reading. A lighting device according to the present invention may also be used for creating functional lighting for specific working issues such as helping the workers vision for e.g. selections of objects, operating machines, appearance of organs and blood vessels for helping surgeons, better appearance of the mouth region to assist dentists, appearance of clothing in stores, lighting for food preparation in home or the industry, lighting for super markets and other stores to highlight the goods in a preferable way

The different aspects of the present invention can be implemented in different ways including the lighting devices and lighting apparatus described above and in the following, each yielding one or more of the benefits and advantages described in connection with at least one of the aspects described above, and each having one or more preferred embodiments corresponding to the preferred embodiments described in connection with at least one of the aspects described above and/or disclosed in the dependant claims. Furthermore, it will be appreciated that embodiments described in connection with one of the aspects described herein may equally be applied to the other aspects.

### BRIEF DESCRIPTION OF THE DRAWINGS

The above and/or additional objects, features and advantages of the present invention, will be further elucidated by the following illustrative and non-limiting detailed description of embodiments of the present invention, with reference to the appended drawings, wherein:

FIG. 1 shows a side view of a lighting device according to an embodiment of the present invention.

FIG. 2 shows a front view of a lighting device according to an embodiment of the present invention.

FIG. 3 shows a top view of a lighting device according to an embodiment of the present invention.

FIG. 4 shows a side view of a lighting device according to an embodiment of the present invention.

FIG. 5a-c Show sectors of the periphery of a lighting device according to an embodiment of the present invention wherein LEDs may be placed.

FIG. 6 Shows a sector of a lighting device according to an embodiment of the present invention wherein LEDs may be placed.

FIG. 7 Shows a perspective view of a lighting apparatus comprising a plurality of lighting devices, according to an embodiment of the present invention.

FIG. 8 shows a side view of a lighting device according to an embodiment of the present invention

FIG. 9 shows a side view of lighting device comprising a control circuit according to an embodiment of the present invention.

FIG. 10 shows an example of an emitted light distribution with and without a phosphorescent optical filter.

### DETAILED DESCRIPTION

In the following description, reference is made to the accompanying figures, which show by way of illustration how the invention may be practiced.

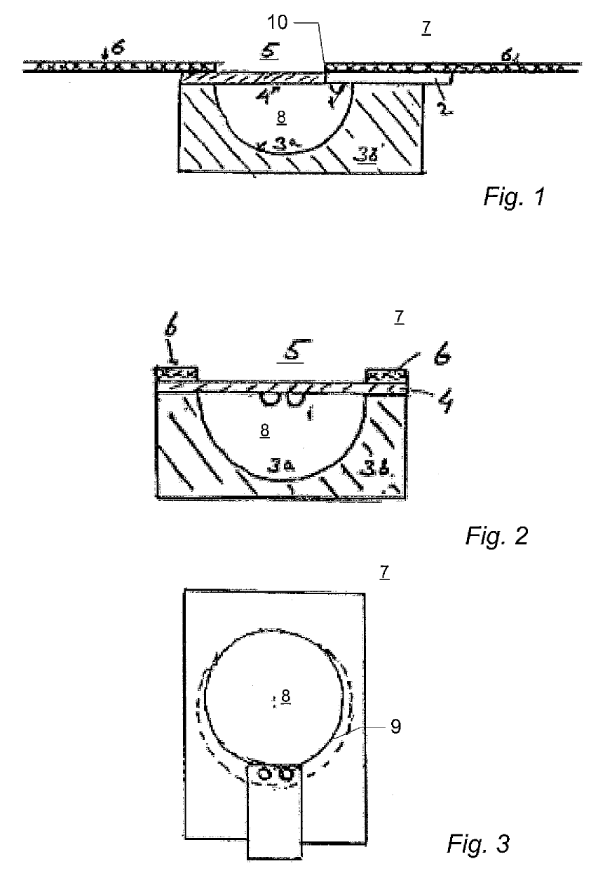

FIGS. 1-3 show a schematic illustration of a lighting device according to an embodiment of the present invention. FIG. 1, shows a side view, FIG. 2 shows a front view and FIG. 3 shows a top view. The lighting device 7 comprises two LEDs 1, a printed circuit board 2, a shielding structure 9, a diffuse reflective surface 3a, a chamber 8, an optical filter 4, an opening 5 and a fixating structure 6. The LEDs generate different coloured light e.g. white and red light. The two LEDs 1 are mounted on the printed circuit board 2 from where they are provided with electrical power. The printed circuit board 2 further forms part of the shielding structure 9. The shielding structure 9 prevents light coming from the LEDs 1 from exiting the opening 5 without being reflected by the diffusely reflective surface 3a at least once. The printed circuit board 2 is positioned in the same plane as the opening 5 of the chamber 8, and the LEDs are positioned on the one side of the printed circuit board “inside” the chamber 8, thereby the LEDs point in the direction directly away from the opening 5, towards the inside of the chamber 8. This secures that the majority of the light generated by the LEDs is directed directly towards the diffuse reflective surface of the chamber.

The printed circuit board 2 is attached to the rim of the dome shaped chamber 8 and extends radially into the dome shaped chamber 8. Hence the edge 10 of the printed circuit board 2 proximal to the centre of the opening of the dome, defines a part of the periphery of the opening 5 of the chamber 8. The LEDs 1, are arranged on the portion of the printed circuit board extending into the chamber 8. In particular the LEDs are positioned on the side of the printed circuit board 2 that faces the inside of the chamber 8. The opposite side of the printed circuit board 2 facing away from the chamber is attached to the fixating structure 6. The fixating structure 6 has the form of a plate having an opening matching the opening of the chamber for allowing the light generated by the lighting device 7 to exit. The optical filter 4 is attached to the rim of the dome shaped chamber 8. The surfaces of the filter 4 and the printed circuit board 2 facing away from the chamber 8 provide a flat surface for mounting the lighting device 7, e.g. to the fixating structure 6. The shielding structure 9 is comprised of the printed circuit board 2 and a part of the fixating structure 6. In alternative embodiments of the invention the shielding structure 9 is formed entirely of the printed circuit board 2 or a combination of the printed circuit board 2 and a supplementary shielding structure, or it may be entirely formed of the fixating structure and/or a supplementary shielding structure. The supplementary shielding structure may be an integral part of the chamber 8, or an independent structure.

The printed circuit board is in good thermal contact with the fixating structure 6 allowing the heat generated from the LEDs 1 to be transferred away through the printed circuit board 2 into the fixating structure 6. The printed circuit board 2 is preferably a printed circuit board with a high thermal conductivity, such as a two- or multi-layer FR4 print with thermal vias or a MCPCB, Metal Core printed circuit board.

Preferably the fixating structure is made of a material with high thermal conductivity, such as a metal e.g. aluminium or copper. In alternative embodiments of the invention no fixating structure is present. The chamber 8 has a round dome like shape. This shape secures a good even directional distribution of the light. By varying the design of the chamber different desired directional characteristics of the light can be achieved. The optical filter 4 is placed in the same plane as the opening of the chamber 5, in direct contact with the printed circuit board 2. In this embodiment the optical filter covers the entire opening of the chamber, thereby securing the chamber against dust. In alternative embodiments of the invention the optical filter 4 is positioned in the same plane as the fixating structure 6 thereby allowing an easy cleaning of the optical filter 4. In yet other embodiments the optical filter 4 may be a transparent glass or even not be present.

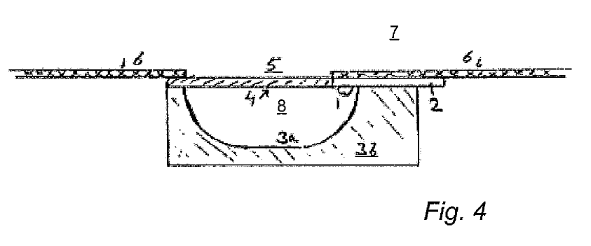

FIG. 4 shows a schematic side view of a lighting device 7 according to an embodiment of the present invention. The lighting device 7 comprises a chamber 8 having a more elongated spherical shape. By varying the shape of the chamber, desired directional properties of the generated light can be achieved.

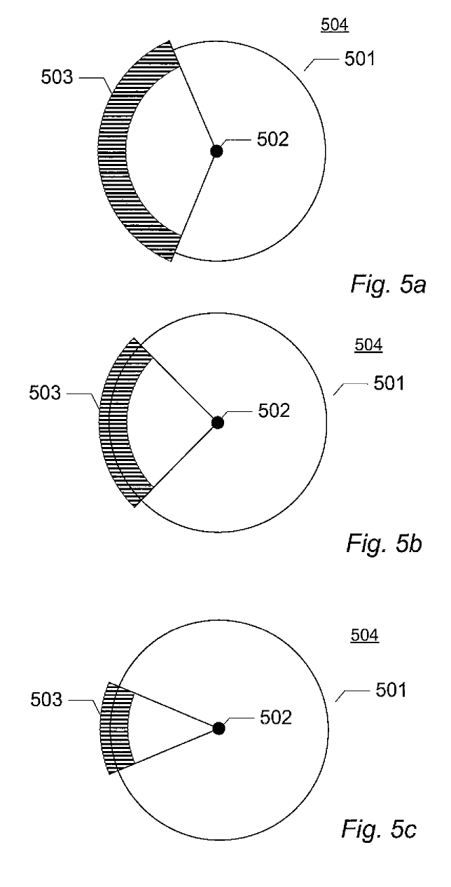

FIGS. 5a-c show sectors of the periphery of an opening of a lighting device, in which the LEDs may be positioned. FIG. 5a shows an opening 504 having a periphery 501 and a centroid 502. The shaded region 503 shows an area where the angular distance between any two points in said area is below 135 degrees. In embodiments of the invention the plurality of LEDs is limited to be positioned in that region. FIG. 5b shows a shaded region 503 where the angular distance between any two points in said area is below 90 degrees, in embodiments of the invention the plurality LEDs are limited to be placed inside the shaded region 503. FIG. 5c shows a shaded region 503 where the angular distance between any two points in said area is below 45 degrees, in embodiments of the invention the plurality LEDs are limited to be placed inside the shaded region 503. It is understood that the region may be placed in any part of the periphery. In the examples shown in FIG. 5a-c the positioning of the shaded regions 503 in a part of the periphery 501 of the opening 504 will not affect the shape of the shaded region due to the circular symmetry of the opening 501.

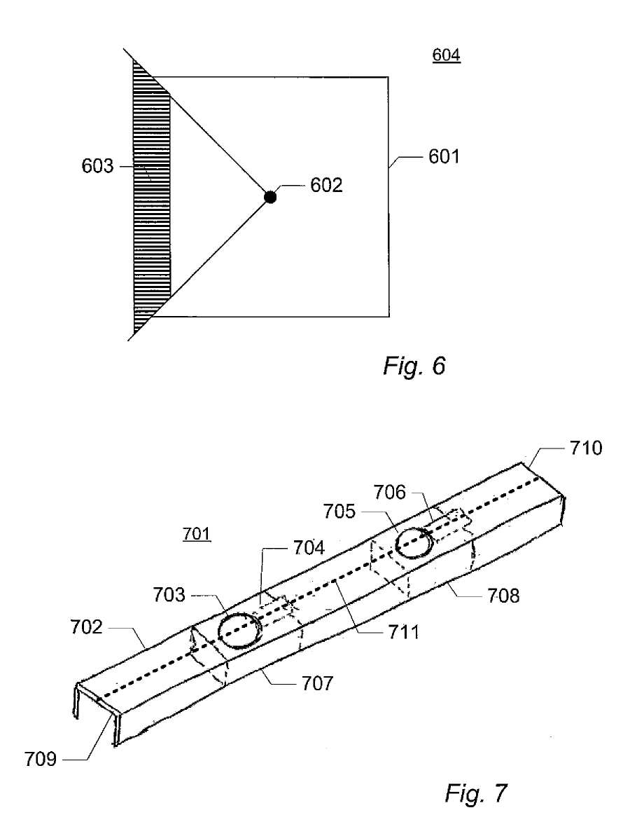

FIG. 6 shows a sector of the periphery of the opening of a lighting device according to an embodiment of the present invention, where LEDs may be placed. Shown is an rectangular opening 604 having a periphery 601 and a centroid 602. The shaded region 603 shows an area where the angular distance between any two points in said area is below 90 degrees. In embodiments of the invention the plurality of LEDs are limited to be positioned in that region. It is understood that the region may be placed in any part of the periphery, in this example the shape of the shaded region will change, depending on which part of the periphery is chosen, as a result of the non circular symmetry of a rectangle.

FIG. 7 shows a lighting apparatus 701 according to an embodiment of the present invention. The lighting apparatus 701 comprise two lighting device 707, 708 as described above fitted into an elongated casing, in this example a rail 702 having an axis 711. Each of the lighting devices 707, 708 comprises a chamber (not shown), an opening 703, 705 and a printed circuit board 704, 706 where on a plurality of LEDs are mounted. In this example the lighting apparatus comprises two lighting devices 707, 708 however it may comprise any number. The individual lighting devices may be adapted to produce light having similar or different spectral properties. The rail 702 is preferably made of a material having high thermal conductivity e.g. a metal e.g. copper or aluminium with an optional matte coating or anodised surface. The rail 702 may be adapted to be connected with other similar rails in each of its ends 709, 710. The ends 709, 710 may comprise electrical contacts means for providing the lighting devices 707, 708 with electrical power. The printed circuit boards 706, 704 with the LEDs of the lighting devices 707, 708 mounted, are positioned such that the LEDs are in proximity of the axis 711. Thereby the entire rail 702 may function as a heat sink for the lighting devices 707, 708.

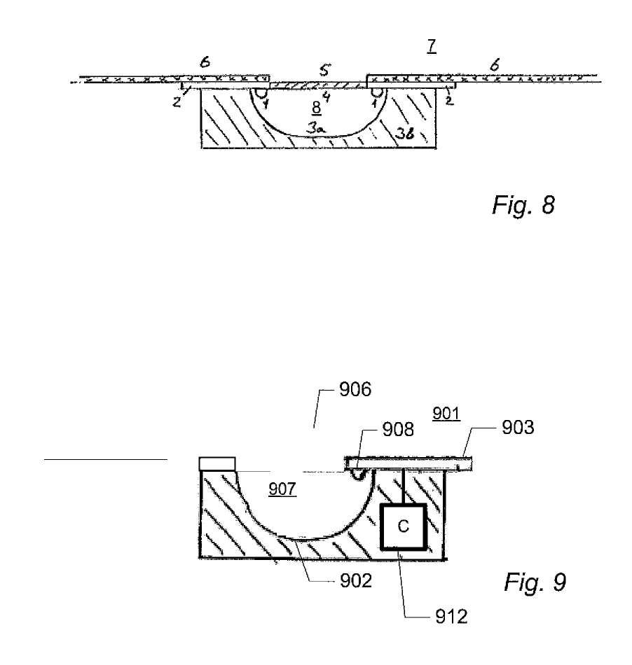

FIG. 8 shows a lighting device according to an embodiment of the present invention. The lighting device 7, comprises a chamber 8 having an elongated spherical shape and a diffusely reflective surface 3a, two printed circuit boards 2 with two groups of LEDs 1 mounted on them, and an optical filter 4 covering the opening 5 of the chamber 8. The two printed circuit boards 2 are placed in good thermal contact with a fixating structure 6, allowing the heat generated by the two groups of LEDs 1 to be transferred away. A group of LED/s may comprise any number of LEDs such as 1, 2, 4, 6 or 8. The two groups of LEDs may comprise identical types of LEDs e.g. a red LED and a white LED each. The area of the opening 5 is significantly larger than the total light emitting surface area of the LEDs 1. Thereby a (soft) diffuse light results with a lower luminance and hence reduced glare. Preferably the surface area of the opening 5 is at least 20 times large than the total light emitting surface area of the LEDs 1. More preferably the surface area of the opening 5 is at least 30 times large than the total light emitting surface area of the LEDs 1.

FIG. 9 shows a lighting device 901 according to an embodiment of the present invention. The lighting device comprises a printed circuit board 903, a group of LEDs 908, a control circuit 912, a chamber 907 and a diffuse reflective surface 902. The control circuit may be configured to control various functionalities of the lighting device, such as the intensity of the individual LEDs.

In an embodiment of the present invention the control circuit is used to allow the lighting device to be dimmed without affecting total spectral radiant flux from the light. A method comprising the following steps may be used to dime the lighting device: First characterise the total spectral radiant flux from the light emitting diodes as a function of operation current and temperature, then determine though simulation and optimization the optimal combined spectral distribution from the used light emitting diodes and the additional optical filter in order to obtain the desired correlated colour temperature and colour rendering properties, next tabelize the drive current or current modulation for each light emitting diode for a range of total radiant flux, corresponding to dimming from 0-100%, then finally for a given dimming value drive the light emitting diodes at the corresponding currents or current modulation factors,

It may be necessary to measure the operation temperature of the device and adjust the operation currents or current modulation factors of the light emitting diodes.

A lighting device according to the present invention may be dimmed using any suitable procedure such as lowering the current through the individual LEDs or using pulse width modulation.

As described above, embodiments of the lighting device described herein may include an optical filter, e.g. the optical filter 4 of FIGS. 1, 2, 4, and 8. The optical filter may be an absorbing or reflective filter adapted to remove or at least reduce unwanted spectral contents from the spectral distribution of the emitted light. In some applications, e.g. in the context of illuminating items in a display case, a museum, and/or the like, it may be desirable to remove blue content and to reduce the correlated color temperature. Alternatively or additionally to absorbing or reflective filters, a wavelength conversion material may be used that absorbs the undesired spectral content (e.g. the blue part of the light) and converts it to a different spectral range (e.g. to red light). This process has the effect of changing the spectral distribution towards a lower correlated color temperature and/or a lower blue content of the emitted light. Furthermore, as the undesired content is not merely removed from the emitted light but converted into a different spectral range, such an embodiment is more energy efficient.

For example, in the display case illumination example, warm white light (e.g. 2200 K) and a relatively low amount of blue light may be desirable due to the degrading effects of short wavelength light. Normally this is done using an absorbing or reflective filter and adding red light.

The wavelength conversion material may be a photoluminescent, i.e. a phosphorescent and/or fluorescent, material.

When using a phosphorescent or fluorescent material instead of an absorbing or reflective filter, some of the blue light is absorbed and re-emitted in the desired wavelength range, here in the red wavelength region. The efficiency will thus be higher in this system since the filtered light is not lost, but converted to light that is added externally otherwise. It may still be desirable to add a small amount of red light anyway in order to achieve the desired color of light. The phosphorescent material has the desired effect of reducing the relative blue content of light. The correlated color temperature of the light is lowered, in one example from 2700 K to around 2000 K

Examples of suitable photoluminescent materials include europium doped Calcium Sulphide which may convert light from about 450 nm to 650 nm. Other fluorescent or phosphorescent materials include Magnesium fluorogermanate doped with manganese, and YAG:Ce. For example, the optical filter may comprise a glass substrate having at least one surface coated with a thin-film layer of a photoluminescent material.

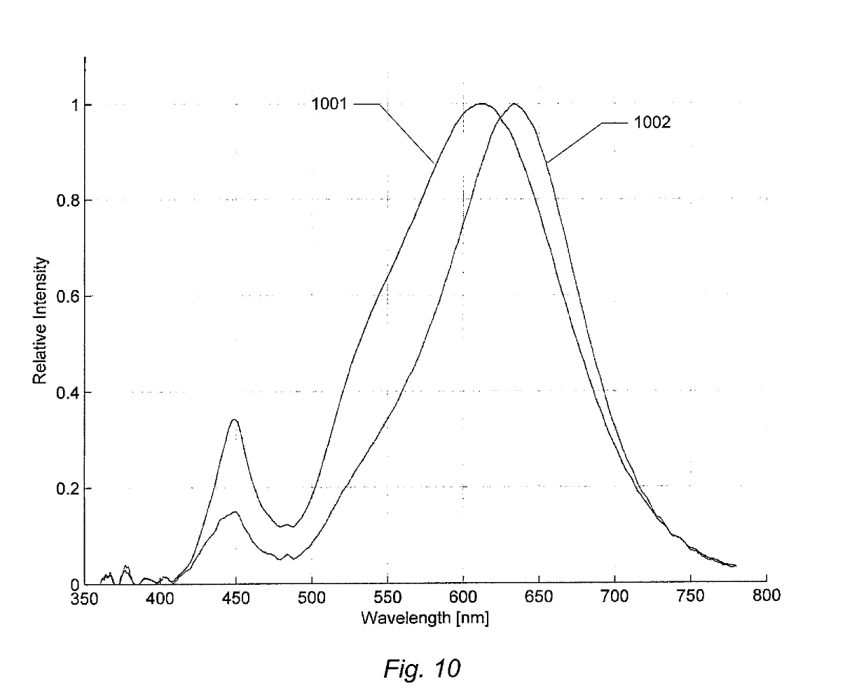

FIG. 10 shows an example of an emitted light distribution with and without a phosphorescent optical filter. In particular, FIG. 10 shows a curve 1001 representing the measured spectral distribution of a normal warm white LED at a CCT of 2700 K, and curve 1002 representing the spectral distribution of light transmitted through a phosphorescent material, in this example europium doped Calcium Sulphide. The transmitted light corresponding to curve 1002 has a CCT of 1967 K, which is 1000 K lower than for curve 1001, and the relative blue content is reduced considerably.

The table below shows the measured light parameters for the two spectral distributions of FIG. 10:

| Curve 1001 | Curve 1002 |
|---|---|
| CCT = 2698 Kelvin | CCT = 1967 Kelvin |
| DC = 7.8e−004 | DC = 5.2e−003 |
| DC <= 5.4e−3 = True | DC <= 5.4e−3 = True |
| Specific CRI indices: | Specific CRI indices: |
| 79.5 | 88.2 |
| 86.8 | 94.7 |
| 91.9 | 96.9 |
| 79.1 | 84.9 |
| 77.3 | 87.0 |
| 80.8 | 94.2 |
| 86.3 | 85.6 |
| 65.0 | 72.6 |
| 20.0 | 48.5 |
| 67.7 | 86.1 |
| 74.9 | 84.3 |
| 60.3 | 87.7 |
| 80.4 | 89.8 |
| 94.6 | 97.0 |
| CRI = 80.8 | CRI = 88.0 |

In the above, the application of photoluminescent materials as part of the optical filter through which the exiting light is transmitted has been described. However, it will be appreciated that photoluminescent or other wavelength converting materials may also be applied as a coating layer (for example a thin film layer) on the reflective surface (e.g. the diffuse reflective surface 3a shown in the above figures), e.g. on top of a base coating that reflects the light. In this case the reflector may initially be painted with a base coating and afterwards with a thin-film layer of phosphorescent material.

Quantum dots are made of semiconductor materials and they work similar to phosphorescent materials, but they allow a more detailed control of the emitted wavelength, and this property leads in many cases to a much better color rendering. The emitting wavelength from the quantum dots can be controlled to emit light everywhere in the visible region by selecting a proper size of the dot and the type of the semiconductor material. By using a combination of several quantum dots, it is possible to obtain different color temperatures. For the display case illumination a low color temperature and a high color rendering index are desirable, and semiconductor dots are very attractive for this purpose.

Although some embodiments have been described and shown in detail, the invention is not restricted to them, but may also be embodied in other ways within the scope of the subject matter defined in the following claims. In particular, it is to be understood that other embodiments may be utilised and structural and functional modifications may be made without departing from the scope of the present invention.

In device claims enumerating several means, several of these means can be embodied by one and the same item of hardware. The mere fact that certain measures are recited in mutually different dependent claims or described in different embodiments does not indicate that a combination of these measures cannot be used to advantage.

It should be emphasized that the term “comprises/comprising” when used in this specification is taken to specify the presence of stated features, integers, steps or components but does not preclude the presence or addition of one or more other features, integers, steps, components or groups thereof.

1. A lighting device for illuminating objects, the lighting device comprising:
a plurality of light emitting diodes wherein at least one of the plurality of light emitting diodes is adapted to generate light having a spectrum different from a spectrum of light generated by another light emitting diode of said plurality of light emitting diodes; and
a chamber comprising a first reflective surface and an opening for allowing light to exit said chamber, said opening having a periphery, wherein the plurality of light emitting diodes are positioned along the periphery of said opening;
characterized in that said opening has a centre point defined as the centroid of said opening, and that said plurality of light emitting diodes are positioned along a limited portion of the periphery of said opening, wherein an angular distance between any two light emitting diodes of said lighting device relative the centre point of the opening is smaller than 135 degrees and said first reflective surface is a diffuse reflective surface.

2. A lighting device according to claim 1, wherein the angular distance between any two light emitting diodes with respect to the centre point is below 90 degrees.

3. A lighting device according to claim 1, wherein the angular distance between any two light emitting diodes with respect to the centre point is below 45 degrees.

4. A lighting device according to claim 1, wherein the angular distance between any two light emitting diodes with respect to the centre point is below 30 degrees.

5. A lighting device according to claim 1, wherein chamber is dome shaped.

6. A lighting device according to claim 1, wherein the plurality of light emitting diodes is adapted to predominantly radiate away from said opening towards the inside of the chamber.

7. A lighting device according to claim 1, wherein the area of said opening of said chamber is at least 20 times larger than the total light emitting surface area of all light emitting diodes of the lighting device.

8. A lighting device according to claim 1, wherein the area of said opening of said chamber is at least 30 times larger than the total light emitting surface area of all light emitting diodes of the lighting device.

9. A lighting device according to claim 1, wherein the lighting device further comprises an optical filter positioned so as to cover at least a part of the opening of the chamber, wherein the optical filter is adapted to modify the spectrum of the light exiting the opening increasing the colour rendering properties of the light.

10. A lighting device according to claim 9, wherein the optical filter comprises a wavelength conversion component adapted to modify the spectral distribution of the light exiting the opening the chamber.

11. A lighting device according to claim 1, wherein at least a part of the diffuse reflective surface comprises a wavelength converting component adapted to cause the reflected light to have a spectral distribution different for a spectral distribution of the light impinging on the diffuse reflective surface.

12. A lighting device according to claim 1, wherein the chamber of said lighting device further comprises a shielding structure wherein said shielding structure is adapted to prevent light rays from said plurality of light emitting diodes to exit said opening without being reflected by said reflective surface at least once.

13. A lighting device according to claim 1, wherein the lighting device further comprises a controlling circuit adapted to modify the relative intensity between the plurality of light emitting diodes for allowing the lighting device to be dimmed without significantly affecting the spectrum of the generated light.

14. A lighting apparatus comprising a plurality of lighting devices as defined in claim 1, wherein the lighting apparatus comprises an elongated casing having a centre line wherein the plurality of lighting devices are arranged along said centre line, and the portion of the periphery of each of the lighting devices along which the respective plurality of light emitting diodes are positioned is in proximity of the centre line.

15. A lighting apparatus according to claim 14, wherein the angle between a line starting in the centre point of the opening of a lighting device and going through any of the plurality of light emitting diodes of said lighting device, and a tangent to said centre line in the centre point of the opening of said lighting device, is at most 45 degrees

16. A lighting apparatus according to claim 14, wherein the angle between a line starting in the centre point of the opening of a lighting device and going through any of the plurality of light emitting diodes of said lighting device, and a tangent to said centre line in the centre point of the opening of said lighting device, is at most 30 degrees.
